(19) United States
(12) Patent Application Publication
(10) Pub. No.: US 2002/0163065 A1
(43) Pub. Date: Nov. 7, 2002

(54) Chip carrier, and method of testing a chip using the chip carrier

(75) Inventors: Wataru Kuwahara, Hyogo (JP); Katsunori Horie, Tokyo (JP)

Correspondence Address: McDermott, Will & Emery, 60013th Street, N.W., Washington, DC, 20005-3096, US

(73) Assignee: Mitsubishi Denki Kabushiki Kaisha

(21) Appl. No.: 09/982,160

(22) Filed: Oct. 19, 2001

(30) Foreign Application Priority Data
May 1, 2001 (JP) 2001-134036

(51) Int. Cl. H01L 23/02

(52) U.S. Cl. 257/678

(57) ABSTRACT

A chip carrier is provided with a carrier base having an opening and being capable of accommodating a chip inside the opening, and an outer lid for closing the opening of the carrier base. The outer lid is engaged with the carrier base when rotated in a space of the carrier base formed over the opening. Hence it is possible to provide a chip carrier that is composed of only a small number of parts, has a relatively simple mechanism, is inexpensive, and facilitates automation of assembling and sharing of test equipment for semiconductor devices, and provides high test efficiency.

### BACKGROUND OF THE INVENTION

1. Field of the Invention

The present invention relates to a chip carrier that is used for a test burn-in, etc., for a chip such as a bare chip, as well as to a method of testing a chip using the chip carrier.

2. Background Art

With the advancement of techniques of mounting a chip on a substrate and packaging techniques such as multi-chip packaging, the need for assuring the quality of a chip before its mounting or packaging is becoming increasingly high. This need is satisfied in such a manner that a chip is tested in a state that it is temporarily accommodated in a chip carrier and thereby the characteristics of the chip as well as whether the chip is good or defective are checked. In this manner, the reliability of a semiconductor device obtained by mounting or packaging the chip after the above testing is assured and the test yield of the semiconductor device is increased.

A conventional chip carrier will be described below with reference to FIGS. 7 and 8.

FIG. 7 is a schematic perspective view of a conventional chip carrier. In FIG. 7, reference numeral 5 denotes a chip (bare chip) as cut out from a wafer; 10 denotes a carrier base for accommodating the chip 5; 11 denotes contacts to be electrically connected to the chip 5; 13 denotes a carrier cover; and 14 denotes a carrier cover lock. Having a hinge mechanism, each of the carrier cover 13 and the carrier cover lock 14 is joined to the carrier base 10 rotatably.

To test the chip 5 using the chip carrier having the above structure, first, the chip 5 is mounted on the contacts 11. Then, the carrier cover 13 is rotated and thereby fitted into the carrier base 10 so as to cover the chip 5 from above. Further, the carrier cover lock 14 is rotated and thereby fitted into or engaged with the carrier base 10 and the carrier cover 13. In this manner, the carrier cover 13 is prohibited from rotation.

The chip carrier thus assembled is mounted in a testing apparatus or the like and subjected to prescribed tests. The chip 5 that has been tested is removed from the chip carrier and another chip 5 is mounted in the chip carrier.

FIG. 8 is a schematic perspective view showing how another conventional chip carrier disclosed in Japanese Patent Laid-Open No. 1996-75819 is assembled. In FIG. 8, reference numeral 3 denotes contacts; 5 denotes a chip; 15 denotes a carrier base; 18 denotes a carrier cover; and 19 denotes carrier cover locks. The carrier cover 18 has, on both sides, step portions into which the carrier cover locks 19 are to be fitted.

In the chip carrier thus configured, first, the chip 5 is mounted on the contacts 3 in the direction indicated by an arrow in FIG. 8. Then, the carrier cover 18 is mounted so as to cover the top surface of the chip 5. Further, the carrier cover locks 19 are engaged with the respective step portions of the carrier cover 18 that are provided on both sides. As a result, the carrier cover 18 is fixed to the carrier base 15.

In the conventional chip carrier shown in FIG. 7 in which each of the carrier cover 13 and the carrier cover lock 14 has the hinge mechanism, to make the sliding portions of the hinge mechanisms sufficiently durable, in many cases the related members are made of a metal or the like. The carrier base 10 is required to have at least spaces for accommodating the hinge mechanisms. As such, this conventional chip carrier has problems that the number of parts is large, the manufacturing cost is high, and it is hard to miniaturize because of the complex structure.

Further, since the shape of the chip carrier is much different from that of an actual packaged semiconductor device, it is difficult to share conventional testing equipment for semiconductor devices; this necessitates introduction of testing equipment dedicated to this chip carrier. Not only does investment in such equipment add to the costs of semiconductor devices but also tests are made inefficient.

In contrast, the conventional chip carrier shown in FIG. 8 has an advantage that it can easily be miniaturized because of the relatively simple structure. However, the chip carrier is difficult to assemble for the following reasons. The carrier cover locks 19 which are to be engaged with the carrier cover 18 from both sides to fix the carrier cover 18 are independent, relatively small parts that are separate from the carrier cover 18 and the carrier base 15. The attachment/detachment direction of the carrier cover locks 19 is different from that of the chip 5 and the carrier cover 18. Further, the mouths of the carrier cover locks 19 need to be expanded in attaching them to the carrier cover 18.

Therefore, if it is attempted to automate the insertion/detachment of the chip 5 to/from the chip carrier, a problem arises that a resulting automatic apparatus will necessarily be complex.

### SUMMARY OF THE INVENTION

The present invention has been made to solve the above problems in the art, and an object of the invention is therefore to provide a chip carrier that is composed of only a small number of parts, has a relatively simple mechanism, and is inexpensive. Another object of the invention is to provide a chip carrier that facilitates automation of assembling and sharing of test equipment for semiconductor devices and provides high test efficiency, as well as to provide a method of testing a chip using the chip carrier.

According to one aspect of the present invention, a chip carrier comprises a carrier base having an opening and being capable of accommodating a chip inside the opening, and an outer lid for closing the opening of the carrier base. The outer lid is engaged with the carrier base when rotated in a space of the carrier base formed over the opening.

Other and further objects, features and advantages of the invention will appear more fully from the following description.

### BRIEF DESCRIPTION OF THE DRAWINGS

FIG. 1 is a schematic perspective view showing how a chip carrier according to the first embodiment is assembled.

FIG. 2 is a schematic perspective view of an assembled chip carrier according to the first embodiment.

FIG. 3 is a schematic perspective view showing how a carrier base of the chip carrier shown in FIG. 1 is assembled.

FIG. 4 is a schematic sectional view of a chip carrier according to the second embodiment.

FIGS. 5a and 5b are a schematic top view and bottom view of the outer lid of the chip carrier shown in FIG. 4.

FIG. 6 is a schematic perspective view showing how a chip carrier according to the third embodiment is assembled.

FIG. 7 is a schematic perspective view of a conventional chip carrier.

FIG. 8 is a schematic perspective view showing how another conventional chip carrier is assembled.

### DETAILED DESCRIPTION OF THE PREFERRED EMBODIMENTS

First Embodiment

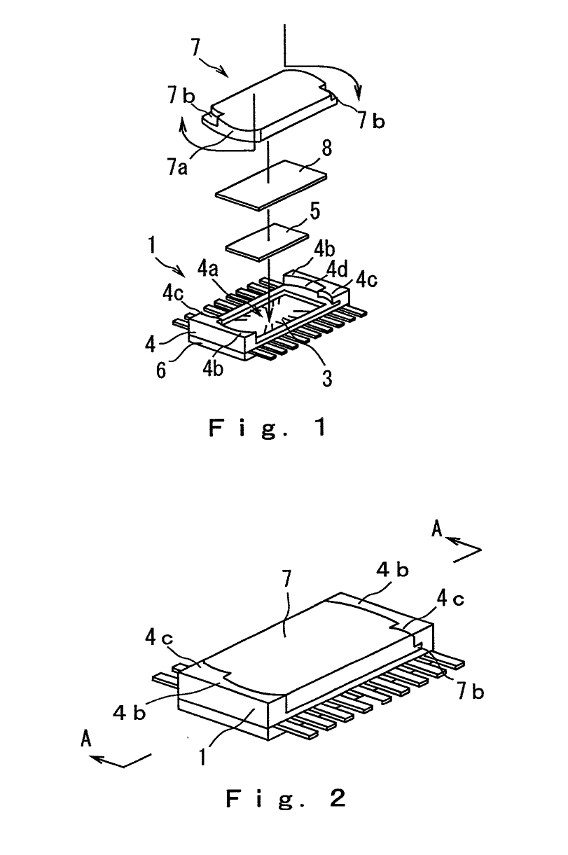

A first embodiment of the present invention will be hereinafter described in detail with reference to the drawings. FIG. 1 is a schematic perspective view showing how a chip carrier according to the first embodiment is assembled. In FIG. 1, reference symbol 1 denotes a carrier base for accommodating a chip or the like; 4a denotes an opening of the carrier base 1; 4b denotes erect portions of the carrier base 1; 4c denotes projections of the respective erect portions 4b; 4d denotes inside surfaces of the respective erect portions 4b; 5 denotes a chip that was cut out of a wafer; 7 denotes an outer lid for closing the opening 4a; 7a denotes a pair of side surfaces of the outer lid 7; 7b denotes recesses in the respective side surfaces 7a; and 8 denotes an inner lid to be accommodated in the carrier base 1.

The erect portions 4b of the carrier base 1 are located on both sides of the opening 4a, and the inside surfaces 4d have an arc shape. The opening 4a of the carrier base 1 is larger than the chip 5 so as to be able to accommodate the chip 5, and has approximately the same shape as the inner lid 8 so as to be able to be fitted with and accommodate the inner lid 8. The pair of side surfaces 7a of the outer lid 7 have an arc shape and are formed with the respective recesses 7b.

In the chip carrier having the above structure, first, the chip 5 is mounted on a contact film 3 in the opening 4a in the direction indicated by the arrow in FIG. 1. For example, this is done by bringing the bumps of the contact film 3 and the pads of the chip 5 into register using an optical positioning means.

Then, the inner lid 8 is placed on the chip 5. At this time, the inner lid 8 is accommodated in the opening 4a so as to be fitted therein. Then, the outer lid 7 is placed on the inner lid 8 and is rotated in the space formed between the erect portions 4b in the direction indicated by the arrows in FIG. 1 and is thereby engaged with the carrier base 1.

The inside surfaces 4d of the carrier base 1 and the side surfaces 7a of the outer lid 7 have such arc shapes that the outer lid 7 can fit in the carrier base 1. Therefore, when the outer lid 7 is rotated, the side surfaces 7a of the outer lid 7 slide on the respective inner surfaces 4d of the carrier base 1.

As shown in FIG. 2, the recesses 7b in the side surfaces 7a of the outer lid 7 are engaged with the projections 4c on the inside surface 4d of the carrier base 1, whereby the assembling of the chip carrier is completed. In this state, the outer lid 7 causes, via the inner lid 8, the chip 5 to be pressed against the contact film 3 with proper force.

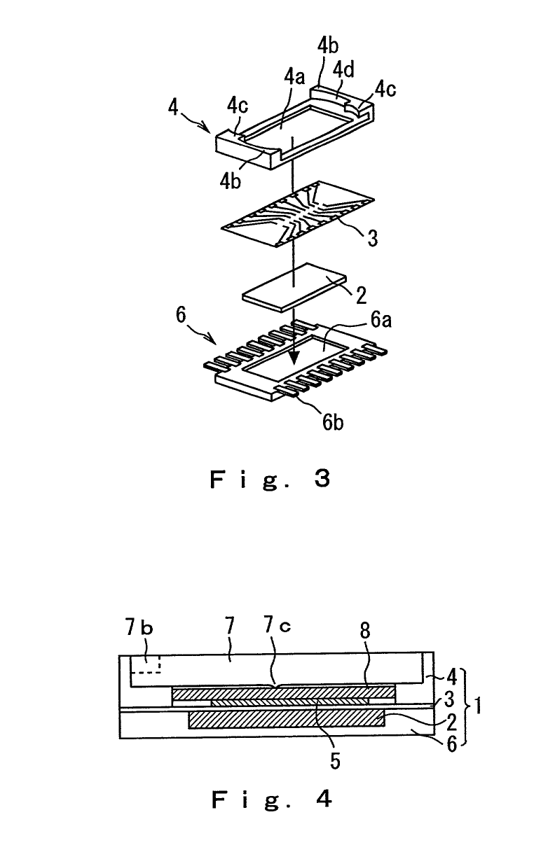

As shown in FIG. 3, the carrier base 1 is composed of a carrier base bottom portion 6, a resin member 2, the contact film 3, and a carrier base top portion 4. The resin member 2 as a cushion member is fitted into a recess 6a of the carrier base bottom portion 6. The contact film 3 is placed on the resin member 2 and then electrically connected to electrodes 6b of the carrier base bottom portion 6. The carrier base top portion 4 is placed on the contact film 3 and then fixed to the carrier base bottom portion 6 by bonding or the like.

Since the carrier base top portion 4 has a penetration opening 4a, the contact film 3 is exposed to the outside through the opening 4a of the carrier base 1 assembled.

The chip carrier according to the first embodiment that is configured as described above is composed of only a small number of parts and has a simple mechanism. The chip carrier can be assembled by sequentially stacking the chip 5, the inner lid 8, and the outer lid 7 on the carrier base 1 in the same direction and finally rotating the outer lid 7 so that it is engaged with the carrier base 1. As such, the assembling consists of only a small number of steps each of which is simple; the assembling can be automated easily.

In particular, since the outer lid 7 is in contact with the inner lid 8 without being in direct contact with the chip 5, the surface of the chip 5 is not rubbed and damaged when the outer lid 7 is rotated. Since the inner lid 8 is accommodated in the opening 4a so as to be fitted in the frame defined by the wall surfaces of the opening 4a, the rotation of the inner lid 8 is prevented with the wall surfaces of the opening 4a serving as stoppers, that is, the inner lid 8 does not rotate in link with the rotation of the outer lid 7. Therefore, there does not occur a phenomenon that deviation in the mounting position of the chip 5 causes a contact defect or the like of the contact film 3.

In the chip carrier 1 according to the first embodiment, it is sufficient to secure spaces for the body portion around the opening 4a and the erect portions 4b in addition to a space for the chip 5. This enables formation of a compact chip carrier 1. Further, since the constituent parts do not include parts that should be particularly durable, all the constituent parts can be made of alight resin. That is, the shape and the material of the chip carrier 1 can be made approximately the same as those of packaged semiconductor devices. Therefore, testing equipment for semiconductor devices can also be used for the chip carrier, whereby the equipment cost can be reduced and the test efficiency can be increased.

The chip carrier according to the first embodiment is particularly suitable for the TSOP, SOJ, BGA, and the like.

In the first embodiment, the outer lid 7 and the carrier base 1 are formed with the recesses 7b and the projections 4c, respectively, and the projections 4c are fitted into the recesses 7b. However, an opposite structure is possible in which the outer lid 7 and the carrier base 1 are formed with projections and recesses, respectively, and the projections are fitted into the recesses. This structure can provide the same advantages as in the first embodiment.

In the first embodiment, the side surfaces 7a of the outer lid 7 and the inner surfaces 4d of the carrier base 1 have arc shapes and the outer lid 7 is engaged with the carrier base 1 by sliding the outer lid 7 along the arc shapes. Another structure is possible in which the side surfaces 7a of the outer lid 7 and the inner surfaces 4d of the carrier base 1 do not have arc shapes but the outer lid 7 can still be engaged with the carrier base 1.

Second Embodiment

A second embodiment of the invention will be hereinafter described in detail with reference to the drawings. A chip carrier according to the second embodiment is different in configuration from the chip carrier according to the first embodiment in that the outer lid has a projection.

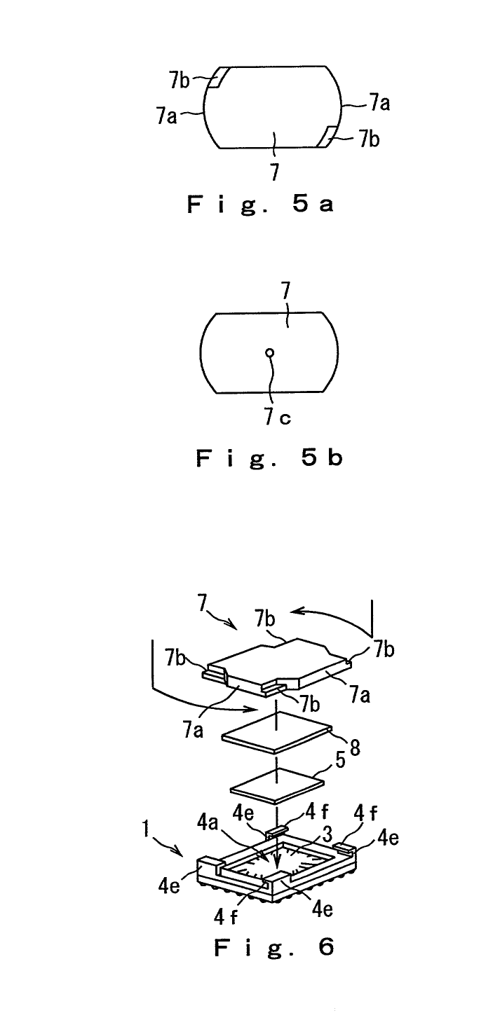

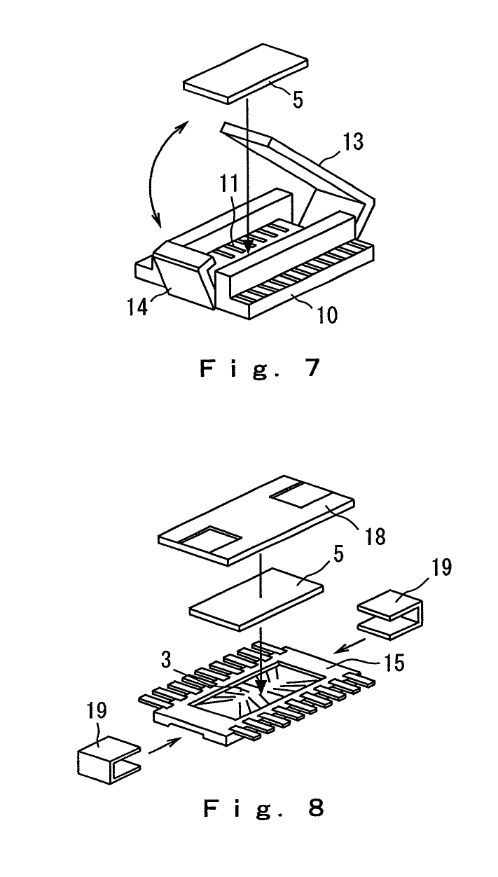

FIG. 4 is a schematic sectional view of a chip carrier according to the second embodiment. FIG. 4 corresponds to a sectional view of the assembled chip carrier of FIG. 2 taken along line A-A in FIG. 2. FIGS. 5a and 5b are a schematic top view and bottom view of the outer lid 7 of the chip carrier shown in FIG. 4.

More specifically, as in the case of the first embodiment, the pair of arc-shaped side surfaces 7a of the outer lid 7 are formed with the respective recesses 7b. As shown in FIG. 5a, the recesses 7b can be seen from above the outer lid 7. The arc shapes of the side surfaces 7a have a constant radius of curvature about the rotation axis about which the outer lid 7 is rotated when engaged with the carrier base 1.

As shown in FIG. 5b, the bottom surface (i.e., the surface to be opposed to the inner lid 8) of the outer lid 7 is formed with a projection 7c. The projection 7c is conical or semispherical, for example, and is formed on the rotation axis of the outer lid 7.

In the chip carrier having the outer lid 7 that is configured as described above, as shown in FIG. 4, the chip 5 is mounted on the contact film 3 of the carrier base 1. The inner lid 8 is mounted on the chip 5. The outer lid 7 having the projection 7c is mounted on the inner lid 8. The outer lid 7 causes, via the inner lid 8, the chip 5 to be pressed against the contact film 3 with proper force.

As in the case of the first embodiment, the outer lid 7 is rotated in the space formed between the erect portions 4b and is thereby engaged with the carrier base 1. Since the projection 7c is formed on the rotation axis, only the projection 7c is in point contact with the inner lid 8 and the other portion of the outer lid 7 is not in contact with the inner lid 8. Therefore, the rotation of the outer lid 7 is completed while causing almost no friction between the outer lid 7 and the inner lid 8. As a result, even if some play exists between the inner lid 8 and the opening 4a, the inner lid 8 don't move in link with the rotation of the outer lid 7.

As described above, the second embodiment can provide a chip carrier that has, in addition to the advantages of the first embodiment, advantages that no positional deviation occurs between the chip 5 and the contact film 3, the reliability is high, and it is assembled easily.

Although in the second embodiment the projection 7c is formed on the surface of the outer lid 7 to be opposed to the inner lid 8, the same advantages as in the second embodiment can also be obtained by forming a projection on the surface of the inner lid 8 to be opposed to the outer lid 7.

Third Embodiment

A third embodiment of the invention will be hereinafter described in detail with reference to the drawings. FIG. 6 is a schematic perspective view showing how a chip carrier according to the third embodiment is assembled. In FIG. 6, reference symbol 1 denotes a carrier base; 4a denotes an opening; 4e denotes erect portions of the carrier base 1; 4f denotes projections of the respective erect portions 4e; 5 denotes a chip; 7 denotes an outer lid; 7a denotes side surfaces of the outer lid 7; 7b denotes recesses formed in the respective side surfaces 7a; and 8 denotes an inner lid.

The chip 5 is approximately square and, to conform to this chip shape, the carrier base 1, the opening 4a, the inner lid 8, and the outer lid 7 are also made approximately square. The erect portions 4e of the carrier base 1 are formed around the opening 4a at the four corners. The inner surfaces of the erect portions 4e are formed with respective projections 4f.

The side surfaces 7a of the outer lid 7 are formed with the respective recesses 7b. The outer lid 7 is so formed as to be slightly smaller than the carrier base 1 so as not contact the erect portions 4e when engaged with the carrier base 1 through rotation, which will be described later. Further, the outer lid 7 is formed with cuts at parts of side surface 7a close to the respective recesses 7b.

In the chip carrier having the above structure, the chip 5 is mounted on the contact film 3 in the opening 4a as in the case of the first embodiment. Then, the inner lid 8 is mounted on the chip 5 so as to be fitted into the opening 4a. Then, the outer lid 7 is rotated in the direction indicated by arrows in FIG. 6 and thereby engaged with the carrier base 1.

As described above, in the chip carrier 1 according to the third embodiment for the square chip 5, to make its shape similar to the chip 5, that is, square, the four erect portions 4e are provided around the opening 4a to enable balanced engagement instead of forming the erect portions 4b having the arc-shaped side surfaces 4d as in the case of the first embodiment.

As described above, as in the case of the first embodiment, the third embodiment can provide a chip carrier that is composed of only a small number of parts and has a simple mechanism and in which the assembling can be automated easily, no positional deviation occurs between the chip 5 and the contact film 3, and the test efficiency is high. In particular, the chip carrier according to the third embodiment is suitable for the CSP and the like.

In the third embodiment, the four erect portions 4e which are provided around the opening 4a of the carrier base 1 are engaged with the four respective recesses 7b of the outer lid 7. The same advantages as in the third embodiment can also be obtained in such a manner that three erect portions 4e are formed around the opening 4a approximately at regular intervals, three recesses 7b are formed in the side surfaces 7a of the outer lid 7 so as to correspond to the respective erect portions 4e, and erect portions 4e are engaged with the respective recesses 7b.

In the third embodiment, the recesses 7b are formed in the outer lid 7, the projections 4f are formed on the carrier base 1, and the projections 4b are engaged with the recesses 7b. Conversely, the same advantages as in the third embodiment can also be obtained in such a manner that projections are formed on the outer lid 7, recesses are formed in the carrier base 1, and the projections are engaged with the recesses.

Although in the third embodiment the chip 5 etc. are approximately square, the shapes of the chip 5 etc. are not limited to such shapes. The same advantages as in the third embodiment can also be obtained even if the chip 5 etc. have other shapes such as rectangles.

The features and advantages of the present invention may be summarized as follows. The invention can provide a chip carrier that is composed of only a small number of parts, has a relatively simple mechanism, and is inexpensive. Further, the invention can provide a chip carrier that is highly reliable without any displacement of a chip during assembling, is assembled easily, and facilitates automation of assembling, as well as a method of testing a chip using the chip carrier. Still further, the invention can provide a compact chip carrier that facilitates sharing of test equipment for semiconductor devices and provides high test efficiency, as well as a method of testing a chip using the chip carrier.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-134036, filed on May 1, 2001 including specification, claims, drawings and summary, on which the Convention priority of the present application is based, are incorporated herein by reference in its entirety.

What is claimed is:

1. A chip carrier comprising:
a carrier base having an opening and being capable of accommodating a chip inside the opening; and
an outer lid for closing the opening of the carrier base,
wherein the outer lid is engaged with the carrier base when rotated in a space of the carrier base formed over the opening.

2. The chip carrier according to claim 1, wherein the carrier base has a pair of erect portions having respective inside surfaces, the erect portions being opposed to each other with the space formed in between, and wherein the outer lid has a pair of side surfaces and is engaged with the carrier base in such a manner that the side surfaces of the outer lid slide on the associated, respective inside surfaces of the erect portions.

3. The chip carrier according to claim 2, wherein the inside surfaces of the erect portions of the carrier base are formed with respective projections or recesses, and wherein the side surfaces of the outer lid are formed with respective recesses or projections to be engaged with the associated, respective projections or recesses of the erect portions of the carrier base.

4. The chip carrier according to claim 2, wherein the inside surfaces of the carrier base and the side surfaces of the outer lid have such arc shapes that the outer lid can fit in the carrier base.

5. The chip carrier according to claim 1, wherein the carrier base has, around the opening, at least three erect portions having inside surfaces that are formed with projections or recesses, and wherein the outer lid has side surfaces that are formed with recesses or projections to be engaged with the associated, respective projections or recesses of the erect portions of the carrier base.

6. The chip carrier according to claim 1, further comprising an inner lid to be disposed between the outer lid and the chip to be accommodated in the carrier base.

7. The chip carrier according to claim 6, wherein a surface of the outer lid to be opposed to the inner lid is formed with a projection on a rotation axis of the outer lid.

8. The chip carrier according to claim 6, wherein a surface of the inner lid to be opposed to the outer lid is formed with a projection at a position to be located on a rotation axis of the outer lid.

9. A method of testing a chip through use of the chip carrier defined in claim 1.
